(19) United States
(12) Patent Application Publication
(10) Pub. No.: US 2015/0123130 A1
(43) Pub. Date: May 7, 2015

(54) TEST KEY STRUCTURE

(71) Applicant: UNITED MICROELECTRONICS CORP., HSINCHU (TW)

(72) Inventors: Mei-Chih Liao, Tainan City (TW); Yi-Fang Tao, Taichung City (TW); Yu-Lin Wang, Taipei City (TW); Chung-Yuan Lee, Taoyuan County (TW)

(73) Assignee: UNITED MICROELECTRONICS CORP., Hsinchu (TW)

(21) Appl. No.: 14/072,905

(22) Filed: Nov. 6, 2013

(51) Int. Cl. H01L 21/66; H01L 29/78; H01L 29/16

(52) U.S. Cl. CPC H01L 22/30; H01L 29/16; H01L 29/78
USPC 257/48

(57) ABSTRACT

A test key structure is provided. The test key structure comprises at least one semiconductor element. Each of the at least one semiconductor element including a well, a source region, a drain region and a gate. The source region is disposed in the well. The drain region is disposed in the well and separated from the source region. The gate is disposed above the well. The source region, the drain region and the well have the same type of doping.

### BACKGROUND

1. Technical Field

The disclosure relates in general to a semiconductor structure, and more particularly to a test key structure.

2. Description of the Related Art

To lower the interface resistance between a source/drain region and a contact thereon, a self-aligned silicide (salicide) process may be applied to the semiconductor devices. The salicide formed between the source/drain region and its corresponding contact provides an interconnect and lowers the interface resistance. However, as the semiconductor devices become smaller, it is more difficult to form the salicide precisely. Thus, current loss due to the salicide may occur.

A test key structure for testing the defect of the semiconductor device, such as the salicide loss described above, may comprise a MOSFET. The MOSFET can be turned on by a voltage applied to the gate. When the MOSFET is turned on, a conductive channel is formed between the source region and the drain region, and thus a current can pass through the MOSFET. However, since the current can pass only when the channel is formed, a tested current loss intrinsically comprises the loss due to the channel resistance. As such, it is difficult to test if the salicide loss occurs.

### SUMMARY

The disclosure is directed to a test key structure for testing the salicide loss.

According to one embodiment, a test key structure comprising at least one semiconductor element is provided. Each of the at least one semiconductor element includes a well, a source region, a drain region and a gate. The source region is disposed in the well. The drain region is disposed in the well and separated from the source region. The gate is disposed above the well. The source region, the drain region and the well have the same type of doping.

### BRIEF DESCRIPTION OF THE DRAWINGS

FIG. 1 shows a semiconductor element according to one embodiment.

FIGS. 2A-2D schematically illustrate a manufacturing process of a semiconductor element according to one embodiment.

FIG. 3 shows a test key structure according to one embodiment.

FIG. 4 shows a test key structure according to another embodiment.

FIGS. 5A-5C schematically illustrate a test process of a test key structure according to one embodiment.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

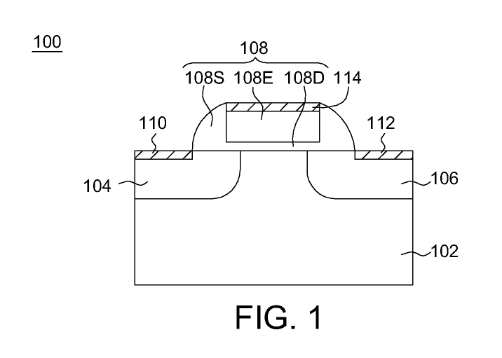

Referred to FIG. 1, an exemplary semiconductor element 100 configured for a test key structure is shown. The semiconductor element 100 has a configuration similar to that of a MOSFET. The semiconductor element 100 includes a well 102, a source region 104, a drain region 106, and a gate 108. The source region 104 is disposed in the well 102. The drain region 106 is disposed in the well 102 and separated from the source region 104. The gate 108 is disposed above the well 102. The source region 104, the drain region 106 and the gate 108 may comprise self-aligned silicide (salicide), such as NiSi or TiSi. In some embodiments, at least the source region 104 and the drain region 106 comprise salicide. In the example shown in FIG. 1, the source region 104, the drain region 106 and the gate 108 comprise salicides 110, 112 and 114, respectively.

Specifically, the source region 104, the drain region 106 and the well 102 have the same type of doping, either p-type or n-type. Since the well 102 has the same doping type as the source region 104 and the drain region 106, it works as a channel for a current to pass. In other words, the semiconductor element 100 keeps turned-on. The current may pass through the semiconductor element 100 via a channel without applying a voltage on the gate 108, thus the tested current loss does not comprise the loss resulted from the channel resistance. As such, the semiconductor element 100 is suitable for the test of the salicide loss of semiconductor devices. In the following description, a semiconductor element 100 having the p-type source region 104, the p-type drain region 106 and the p-type well 102 may be referred to as a p-type semiconductor element 100, and a semiconductor element 100 having the n-type source region 104, the n-type drain region 106 and the n-type well 102 may be referred to as a n-type semiconductor element 100.

While the doping type is the same, the doping concentration of the well 102 keeps different from the doping concentration of the source region 104/drain region 106. A doping concentration of the source region 104 and a doping concentration of the drain region 106 are higher than a doping concentration of the well 102. For example, in some embodiments, the doping concentrations of the source region 104 and the drain region 106 may be about 10¹⁵ cm⁻³, while the doping concentration of the well 102 may be about 10¹³ cm⁻³.

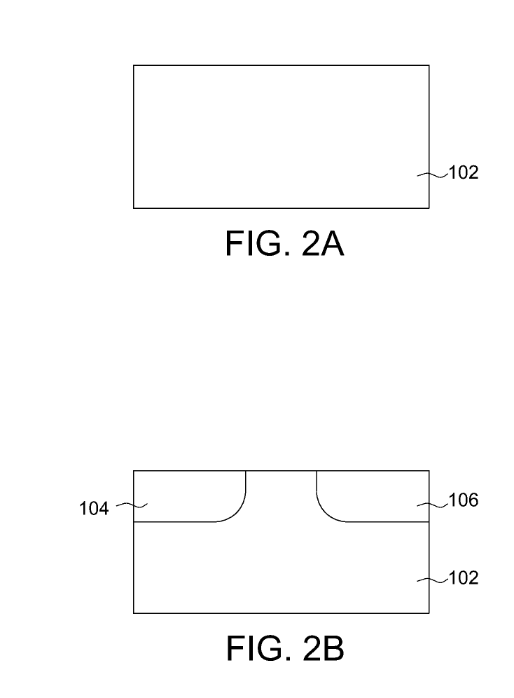

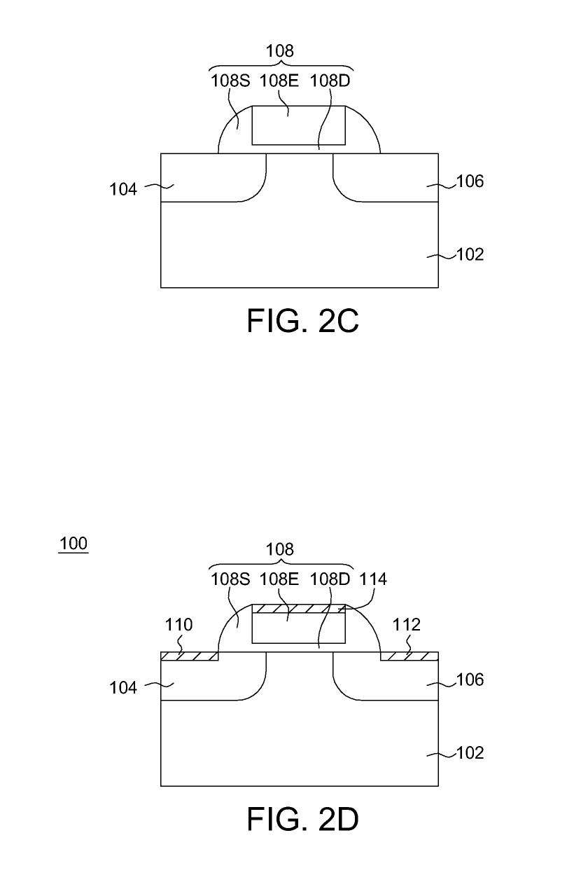

Referring to FIGS. 2A-2D, a manufacturing process of the semiconductor element 100 is schematically illustrated. Firstly, as shown in FIG. 2A, the well 102 is formed by implanting dopants into a substrate (not shown). The dopants may be either p-type dopants or n-type dopants. In some embodiment, the doping concentration is, for example, about 10¹³ cm⁻³.

Thereafter, as shown in FIG. 2B, the source region 104 and the drain region 106 are formed in the well 102 by implantation. The source region 104 and the drain region 106 are separated from each other. Different from the typical manufacturing process of a MOSFET, the source region 104 and the drain region 106 are formed with dopants whose type of doping is the same as that of the well 102. That is, in the cases that the well 102 is formed with p-type dopants, the source region 104 and the drain region 106 are also formed with p-type dopants. While in the cases that the well 102 is formed with n-type dopants, the source region 104 and the drain region 106 are also formed with n-type dopants. In some embodiment, the doping concentration is, for example, about 10¹⁵ cm⁻³.

Referred to FIG. 2C, after the formation of the source region 104 and the drain region 106, the gate 108 is formed above the well 102. The gate 108 is disposed between the source region 104 and the drain region 106. Typically, the gate 108 comprises a dielectric layer (not indicated) and an electrode layer (not indicated) isolated from the source region 104 and the drain region 106 by the dielectric layer.

In some embodiments, the manufacturing process of the semiconductor element 100 may further comprise a salicide process. As shown in FIG. 2D, the source region 104, the drain region 106 and the gate 108 are reacted to form the salicides 110, 112 and 114 thereof, respectively.

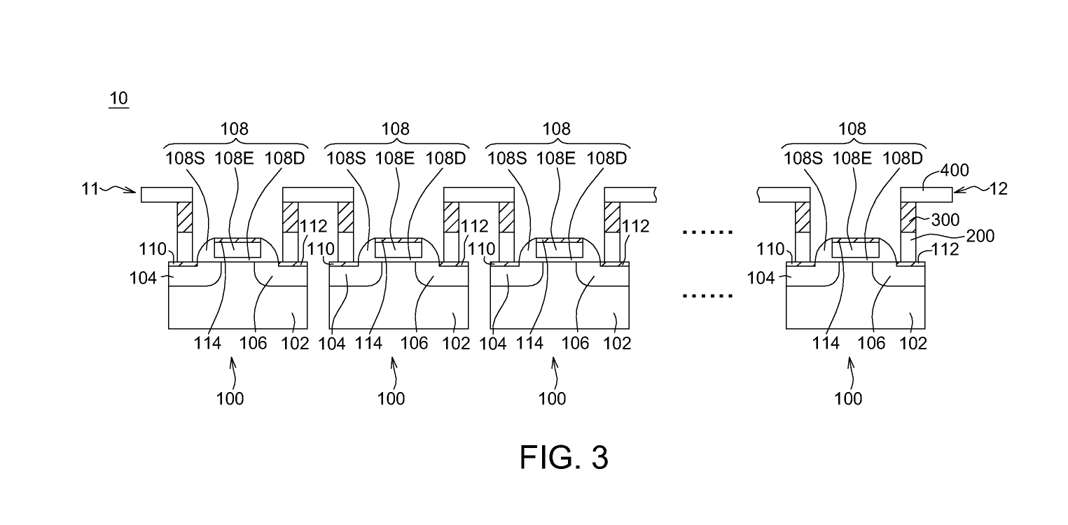

A test key structure may comprise one or more semiconductor elements 100. Referred to FIG. 3, a test key structure 10 according to one embodiment is shown. The number of the semiconductor elements 100 of the test key structure 10 is equal to or more than two.

The semiconductor elements 100 of the test key structure 10 are electrically connected in series. In some embodiments, as shown in FIG. 3, the semiconductor elements 100 are electrically connected in series by connecting one of the source regions 104 and one of the drain regions 106 which are adjacent to each other. In the example shown in FIG. 3, the semiconductor elements 100 are electrically connected by conductive layers 200, 300 and 400. In some embodiments, the conductive layer 200 is a metal layer or a contact. In some embodiments, the conductive layer 300 comprises a plurality of vias. In some embodiments, the conductive layer 400 is a metal layer.

A high voltage may be applied to one end 11 of the test key structure 10 for test, while the other end 12 of the test key structure 10 is grounded. In some embodiments, the gates 108 are floating since the current is able to pass through the semiconductor elements 100 via a channel without applying a voltage on the gate 108. In some other embodiments, a voltage may be applied to the gates 108 to enlarge the channel in each semiconductor element 100. In such conditions, the current can pass the semiconductor elements 100 through a path with lower resistance, i.e., the path through the channels. Compared the test result of the test key structure 10 to the test results relating to the interface failure between the conductive layers 200 and 300, and between the conductive layers 300 and 400, which are ordinarily tested by other test key structures, a tester is able to know if salicide loss occurs in the semiconductor device.

In some embodiments, as the example of FIG. 3, the semiconductor elements 100 of a test key structure are the same type, either the p-type semiconductor elements 100 or the n-type semiconductor elements 100.

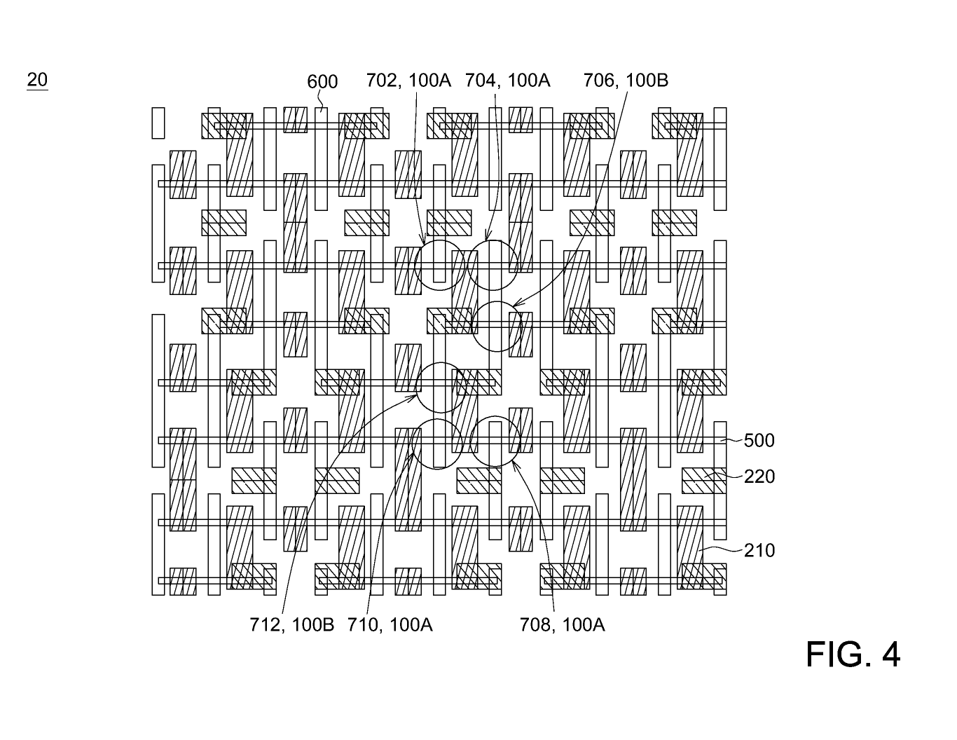

In some other embodiments, as the examples of following figures (for example, FIG. 4), the semiconductor elements 100 of a test key structure may comprise different types. Some of the semiconductor elements 100 of the test key structure may be p-type, and others may be n-type.

Referred to FIG. 4, a test key structure 20 according to another embodiment is shown. The test key structure 20 is illustrated as a test key structure for SRAM. In FIG. 4, metal layers 210 and 220, poly-Si layer 500, and active area 600 are shown, and corresponding positions 702˜712 of some semiconductor elements 100 (first semiconductor elements 100A and second semiconductor elements 100B) are indicated. The semiconductor elements 100 of the test key structure 20 comprise first semiconductor elements 100A and second semiconductor elements 1006, wherein the type of doping of the source region 104, the drain region 106 and the well 102 of the second semiconductor elements 1006 is different from that of the first semiconductor elements 100A. In cases that the first semiconductor elements 100A are n-type, the second semiconductor elements 100B are p-type. In other words, the test key structure 20 comprises both the p-type and the n-type semiconductor elements 100.

In some embodiments, the semiconductor elements 100 at the positions 702 and 708 corresponds to the passing-gate transistors of the SRAM, the semiconductor elements 100 at the positions 704 and 710 corresponds to the pull-down transistors of the SRAM, and the semiconductor elements 100 at the positions 706 and 712 corresponds to the pull-up transistors of the SRAM. In such conditions, the first semiconductor elements 100A may be n-type semiconductor elements 100, and the second semiconductor elements 1006 may be p-type semiconductor element 100.

While both of the p-type semiconductor element 100 and the n-type semiconductor elements 100 are comprised in the test key structure 20, they can be tested by applying the test voltages to each kind of the semiconductor elements 100 separately. More specifically, the first semiconductor elements 100A at the positions 702 and 708, the first semiconductor elements 100A at the positions 704 and 710, and the second semiconductor elements 100B at the positions 706 and 712 can be tested individually by different voltage applications, in order to obtain the salicide loss conditions of the passing-gate transistors, the pull-down transistors, and the pull-up transistors, respectively.

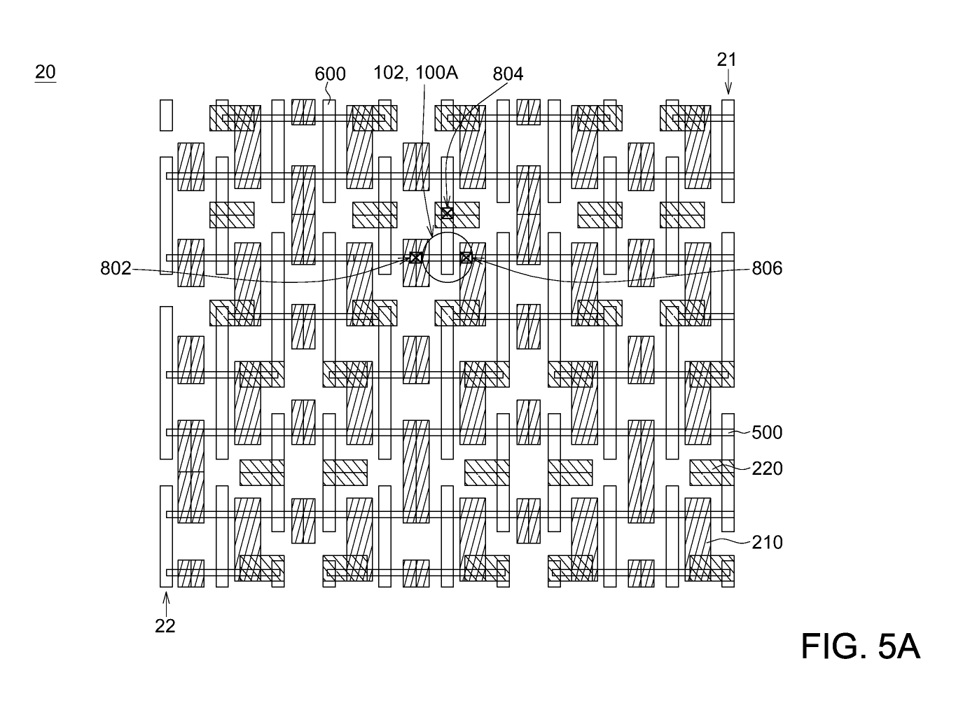

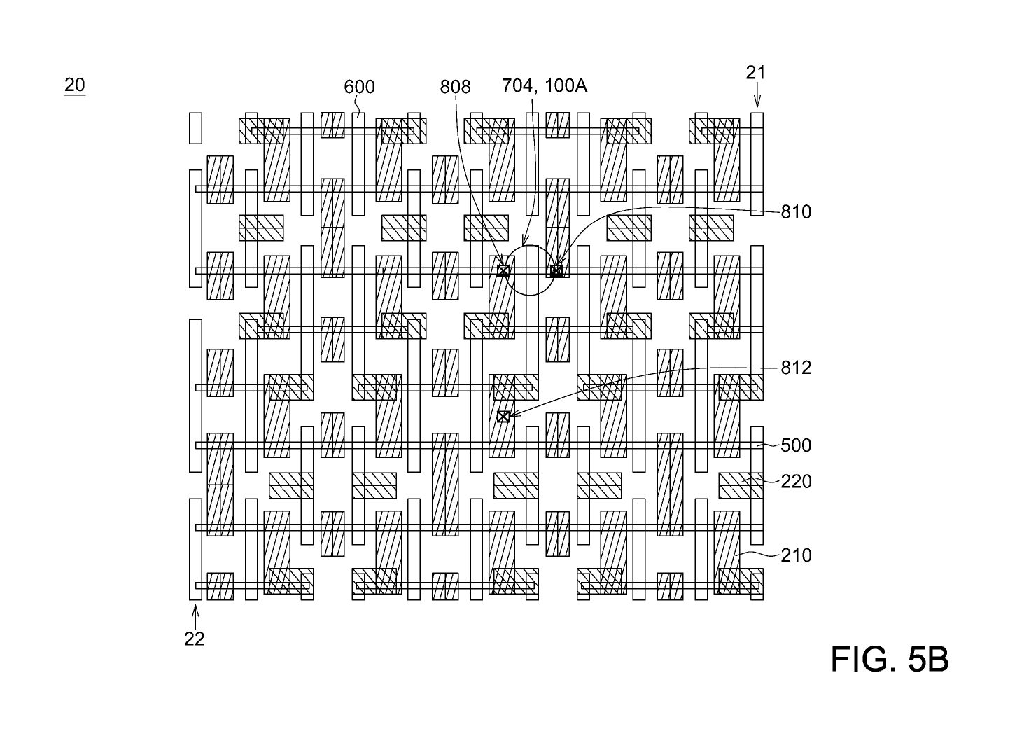

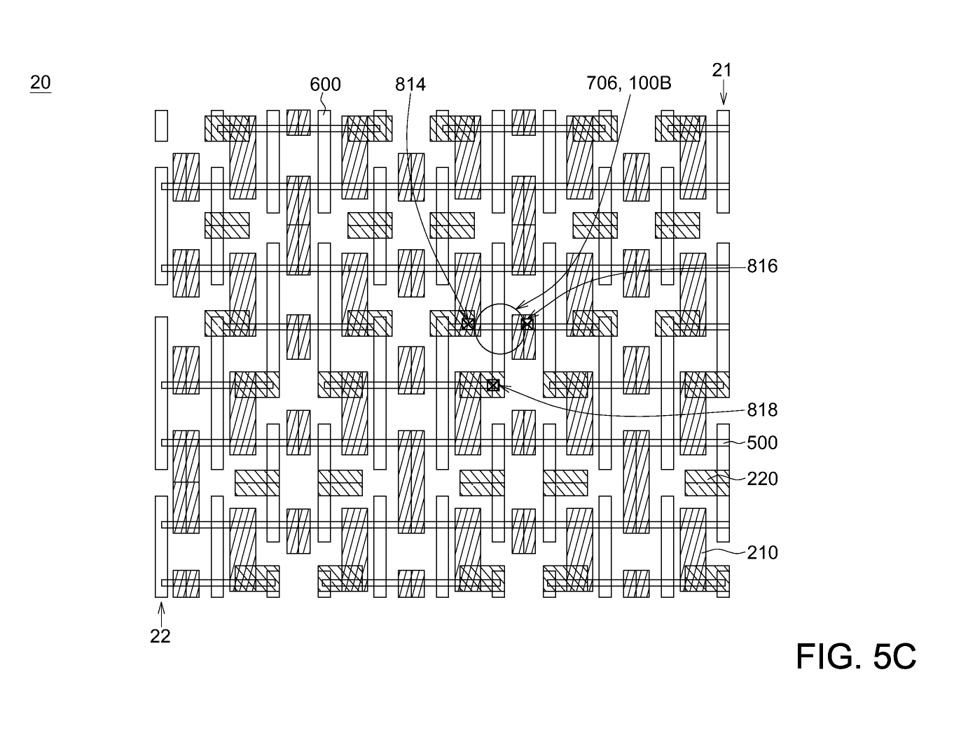

For example, referred to FIGS. 5A-5C, which schematically illustrate a test process of the test key structure 20 for SRAM according to one embodiment. In each figure, only a representative semiconductor element 100 (the semiconductor element 100A or 1008) is shown for clarity.

Referred to FIG. 5A, in cases that a salicide loss condition of the passing-gate transistors is wondered, a tester may apply a high voltage at one end 21 of the test key structure 20, and ground the other end 22 of the test key structure 20. A current is able to pass the first semiconductor element 100A at the position 702, as well as other first semiconductor elements 100A at positions corresponding the position 702, through their well 102. The current passing through these first semiconductor elements 100A is tested and used to obtain the salicide loss condition of the passing-gate transistors. Further, in some embodiment, a voltage may be applied to the gate 108 of the first semiconductor element 100A at the position 702 through positions 802, 804 and 806, such that an additional low-resistance channel for current passage can be formed in this first semiconductor element 100A. The voltage may also be applied to those first semiconductor elements 100A at the positions corresponding the position 702 to form additional channels therein. The first semiconductor element 100A at the position 708, as well as other first semiconductor elements 100A at positions corresponding the position 708, can be tested in the same manner.

Referred to FIG. 5B, in cases that a salicide loss condition of the pull-down transistors is wondered, the tester may apply a high voltage at the end 21 of the test key structure 20, and ground the end 22 of the test key structure 20. A current is able to pass the first semiconductor element 100A at the position 704, as well as other first semiconductor elements 100A at positions corresponding the position 704, through their well 102. The current passing through these first semiconductor elements 100A is tested and used to obtain the salicide loss condition of the pull-down transistors. Further, in some embodiment, a voltage may be applied to the gate 108 of the first semiconductor element 100A at the position 704 through positions 808, 810 and 812, such that an additional low-resistance channel for current passage can be formed in this first semiconductor element 100A. The voltage may also be applied to those first semiconductor elements 100A at the positions corresponding the position 704 to form additional channels therein. The first semiconductor element 100A at the position 710, as well as other first semiconductor elements 100A at positions corresponding the position 710, can be tested in the same manner.

Referred to FIG. 5C, in cases that a salicide loss condition of the pull-up transistors is wondered, the tester may apply a high voltage at the end 21 of the test key structure 20, and ground the end 22 of the test key structure 20. A current is able to pass the second semiconductor element 100B at the position 706, as well as other second semiconductor elements 100B at positions corresponding the position 706, through their well 102. Then, the current passing through these second semiconductor elements 100B is tested and used to obtain the salicide loss condition of the pull-up transistors. Further, in some embodiment, a voltage may be applied to the gate 108 of the second semiconductor element 100B at the position 706 through positions 814, 816 and 818, such that an additional low-resistance channel for current passage can be formed in this second semiconductor element 1008. The voltage may also be applied to those second semiconductor elements 1008 at the positions corresponding the position 706 to form additional channels therein. The second semiconductor element 100B at the position 712, as well as other second semiconductor elements 100B at positions corresponding the position 712, can be tested in the same manner.

In summary, the test key structure according to embodiments described herein comprises at least one semiconductor element, wherein the source region, the drain region and the well of the semiconductor element have the same type of doping. As such, the semiconductor element keeps turned-on, and a current can pass therethrough, even without a voltage applied to the gate of the semiconductor element. Thus, due to the decrease or eliminate of the current loss resulted from the channel resistance, the test key structure comprising such a semiconductor element is suitable for the test of the salicide loss of the semiconductor devices.

The test key structure according to embodiments described herein is particularly suitable for the test of the semiconductor devices with high density, such as SRAM, since these semiconductor devices face more severe salicide loss problem.

It will be apparent to those skilled in the art that various modifications and variations can be made to the disclosed embodiments. It is intended that the specification and examples be considered as exemplary only, with a true scope of the disclosure being indicated by the following claims and their equivalents.

1. A test key structure, comprising:
at least one semiconductor element, each of the at least one semiconductor element including:
a well,
a source region disposed in the well,
a drain region disposed in the well and separated from the source region, and
a gate disposed above the well;
wherein the source region, the drain region and the well have the same type of doping.

2. The test key structure according to claim 1, wherein the source region and the drain region comprise self-aligned silicide.

3. The test key structure according to claim 2, wherein the self-aligned silicide is NiSi or TiSi.

4. The test key structure according to claim 1, wherein the type of doping is p-type.

5. The test key structure according to claim 1, wherein the type of doping is n-type.

6. The test key structure according to claim 1, wherein the number of the semiconductor elements is equal to or more than two, and the semiconductor elements are electrically connected in series.

7. The test key structure according to claim 6, wherein the semiconductor elements are electrically connected in series by connecting one of the source regions and one of the drain regions which are adjacent to each other.

8. The test key structure according to claim 6, wherein the at least one semiconductor element comprises a first semiconductor element and a second semiconductor element, the type of doping of the source region, the drain region and the well of the second semiconductor element is different from that of the first semiconductor element.

9. The test key structure according to claim 1, wherein a doping concentration of the source region and a doping concentration of the drain region are higher than that of the well.

10. The test key structure according to claim 1, wherein the gate is floating.
